(19) United States
(12) Patent Application Publication
(10) Pub. No.: US 2013/0104976 A1
(43) Pub. Date: May 2, 2013

(54) SOLAR CELL WITH INTERCONNECTION SHEET, SOLAR CELL MODULE, AND METHOD FOR MANUFACTURING SOLAR CELL WITH INTERCONNECTION SHEET

(71) Applicant: Kenji Yasutake, Osaka-shi (JP)

(72) Inventor: Kenji Yasutake, Osaka-shi (JP)

(73) Assignee: SHARP KABUSHIKI KAISHA, Osaka-shi, Osaka (JP)

(21) Appl. No.: 13/807,991

(22) PCT Filed: Jun. 24, 2011
(86) PCT No.: PCT/JP2011/064525

§ 371 Date: Jan. 2, 2013

(30) Foreign Application Priority Data
Jul. 1, 2010 (JP) 2010-151070

(51) Int. Cl. H01L 31/0224; H01L 31/18

(52) U.S. Cl. CPC H01L 31/022441; H01L 31/18
USPC 136/256; 438/98

(57) ABSTRACT

There is provided a solar cell with an interconnection sheet, wherein a first wiring of the interconnection sheet is made of a material that is less likely to cause ion migration than a metal material forming a first electrode of the solar cell, and a width of the first wiring is larger than a width of the first electrode. There is also provided a solar cell module including the solar cell with the interconnection sheet, and a method for manufacturing the solar cell with the interconnection sheet.

### TECHNICAL FIELD

The present invention relates to a solar cell with an interconnection sheet, a solar cell module and a method for manufacturing a solar cell with an interconnection sheet.

### BACKGROUND ART

In recent years, development of clean energy is demanded for environmental issues such as depletion of energy resources, increase of CO₂ in the atmosphere, and the like, and in particular, solar photovoltaic power generation employing solar cells is developed, put to practical use and advanced as a new energy source.

As to a solar cell, a bifacial electrode type solar cell produced by diffusing an impurity having a conductivity type opposite to the conductivity type of a silicon substrate into a light receiving surface of a monocrystalline or polycrystalline silicon substrate thereby forming a p-n junction and forming electrodes on the light receiving surface of the silicon substrate and the back surface of the silicon substrate opposite to the light receiving surface, respectively, has been mainstreamed conventionally. In the bifacial electrode type solar cell, it has also become general to attain a high output with a back surface field effect by diffusing an impurity of the same conductivity type as the silicon substrate into the back surface of the silicon substrate in a high concentration.

Further, a back electrode type solar cell prepared by forming an n electrode and a p electrode only on a back surface of a silicon substrate without forming electrodes on a light receiving surface of the silicon substrate is also in the process of research and development (refer to Patent Literature 1 (Japanese Patent Laying-Open No. 2006-332273), for example). In such a back electrode type solar cell, it is unnecessary to form an electrode for blocking the incident light on the light receiving surface of the silicon substrate. Therefore, improvement of the conversion efficiency of the solar cell is expected. A solar cell with an interconnection sheet formed by connecting an electrode of the solar cell to a wiring of the interconnection sheet is also in the process of technological development.

### CITATION LIST

### Patent Literature

PTL 1: Japanese Patent Laying-Open No. 2006-332273

### SUMMARY OF INVENTION

### Technical Problem

A metal material is usually used for the electrode of the solar cell and the wiring of the interconnection sheet. The metal material, however, has the property of ion migration that the metal material ionized by the electric field is precipitated along the direction of the electric field. Whether this ion migration is likely to occur or not depends on the type of the metal material and the electric field strength of the electric field if the ambient temperature and humidity are constant.

It has also been found that there is a close relationship between the conversion efficiency and a pitch between the p electrode and the n electrode, and the conversion efficiency tends to become higher as the pitch between the electrodes becomes narrower. On the other hand, when the pitch between the electrodes is narrowed, the electric field strength of the electric field generated between the electrodes increases. Therefore, ion migration is promoted and short circuit occurs between the electrodes, which may lead to decrease in the conversion efficiency.

In view of the above-mentioned circumstance, an object of the present invention is to provide a solar cell with an interconnection sheet, a solar cell module and a method for manufacturing a solar cell with an interconnection sheet, in which lowering of the properties caused by ion migration of a metal material can be suppressed in a stable manner.

### Solution to Problem

The present invention is directed to a solar cell with an interconnection sheet, including: a solar cell provided with a first electrode on one surface of a substrate; and an interconnection sheet provided with a first wiring electrically connected to the first electrode, wherein the first wiring is made of a material that is less likely to cause ion migration than a metal material forming the first electrode, and a width of the first wiring is larger than a width of the first electrode.

Preferably, in the solar cell with the interconnection sheet according to the present invention, a difference between the width of the first wiring and the width of the first electrode is 40 μm or larger.

Preferably, in the solar cell with the interconnection sheet according to the present invention, a surface of the first electrode contains silver and the first wiring contains copper.

Preferably, in the solar cell with the interconnection sheet according to the present invention, a second electrode having a polarity different from that of the first electrode is arranged on the one surface of the substrate, the interconnection sheet is provided with a second wiring electrically connected to the second electrode, the second wiring is made of a material that is less likely to cause ion migration than a metal material forming the second electrode, and a width of the second wiring is larger than a width of the second electrode.

Preferably, in the solar cell with the interconnection sheet according to the present invention, a difference between the width of the second wiring and the width of the second electrode is 40 μm or larger.

Preferably, in the solar cell with the interconnection sheet according to the present invention, a surface of the second electrode contains silver and the second wiring contains copper.

Preferably, in the solar cell with the interconnection sheet according to the present invention, the solar cell is a back electrode type solar cell.

The present invention is also directed to a solar cell module, including the solar cell with the interconnection sheet as recited in any one of the foregoing.

The present invention is also directed to a method for manufacturing a solar cell with an interconnection sheet including a solar cell provided with an electrode on one surface of a substrate and an interconnection sheet provided with a wiring made of a material that is less likely to cause ion migration than a metal material forming the electrode, the method including the step of: electrically connecting the electrode and the wiring such that the electrode does not protrude from the wiring at least in a width direction.

Preferably, in the method for manufacturing the solar cell with the interconnection sheet according to the present invention, a width of the wiring is larger than a width of the electrode.

### Advantageous Effects of Invention

According to the present invention, there can be provided a solar cell with an interconnection sheet, a solar cell module and a method for manufacturing a solar cell with an interconnection sheet, in which lowering of the properties caused by ion migration of a metal material can be suppressed in a stable manner.

### BRIEF DESCRIPTION OF DRAWINGS

FIG. 1 is a schematic cross-sectional view of a solar cell with an interconnection sheet according to a first embodiment.

FIG. 2 is a schematic enlarged cross-sectional view of a portion connecting a silver electrode of the solar cell and a copper wiring of the interconnection sheet and its surrounding portion, in a portion corresponding to one cycle of the solar cell with the interconnection sheet used in simulation.

FIGS. 3(a) and 3(b) are diagrams showing a result obtained by simulating a change in electric field strength distribution of the solar cell with the interconnection sheet according to the first embodiment.

FIG. 4 is a graph showing a relationship between an amount of protrusion of the silver electrode (μm) and an electric field strength (V/mm) when the amount of protrusion of the silver electrode is variously changed and simulation is performed.

FIG. 5 is a graph showing ion migration sensitivity of various types of metal materials.

FIGS. 6(a) to 6(e) are schematic cross-sectional views illustrating one example of a method for manufacturing the solar cell.

FIGS. 7(a) to 7(d) are schematic cross-sectional views illustrating one example of a method for manufacturing the interconnection sheet.

FIGS. 8(a) to 8(c) are schematic cross-sectional views illustrating one example of a method for manufacturing the solar cell with the interconnection sheet according to the first embodiment.

FIG. 9 is a schematic cross-sectional view of a modification of the solar cell with the interconnection sheet according to the first embodiment.

FIG. 10 is a schematic cross-sectional view of a solar cell module including the solar cell with the interconnection sheet according to the first embodiment.

FIG. 11 is a schematic cross-sectional view of a solar cell with an interconnection sheet according to a second embodiment.

### DESCRIPTION OF EMBODIMENTS

Embodiments of the present invention will be described hereinafter. In the drawings of the present invention, the same reference characters denote the same or corresponding portions.

### First Embodiment

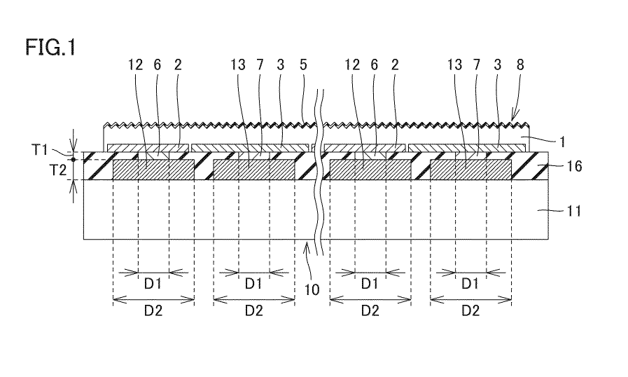

FIG. 1 shows a schematic cross-sectional view of a solar cell with an interconnection sheet according to a first embodiment, which is one example of a solar cell with an interconnection sheet according to the present invention. The solar cell with the interconnection sheet according to the first embodiment includes a solar cell 8 and an interconnection sheet 10, and has such a structure that solar cell 8 is placed on interconnection sheet 10.

Solar cell 8 has a substrate 1, an n-type impurity diffusion region 2 and a p-type impurity diffusion region 3 formed to be arranged alternately on a back surface of substrate 1, a silver electrode for n type 6 (a thickness T1 and a width D1) formed to be in contact with n-type impurity diffusion region 2, and a silver electrode for p type 7 (thickness T1 and width D1) formed to be in contact with p-type impurity diffusion region 3.

An uneven structure such as a textured structure is formed on a light receiving surface of substrate 1, and an anti-reflection film 5 is formed to cover the uneven structure. A passivation film or the like may, for example, be formed on the back surface of substrate 1.

N-type impurity diffusion region 2 and p-type impurity diffusion region 3 are each formed in the shape of a strip extending to the front surface side and/or the back surface side on the plane of sheet of FIG. 1. N-type impurity diffusion regions 2 and p-type impurity diffusion regions 3 are arranged alternately on the back surface of substrate 1 at prescribed spacings therebetween.

Silver electrode for n type 6 and silver electrode for p type 7 are also each formed in the shape of a strip extending to the front surface side and/or the back surface side on the plane of sheet of FIG. 1. Silver electrode for n type 6 and silver electrode for p type 7 are formed along n-type impurity diffusion region 2 and p-type impurity diffusion region 3, respectively.

Interconnection sheet 10 has an insulating base material 11, and a copper wiring for n type 12 (a thickness T2 and a width D2) and a copper wiring for p type 13 (thickness T2 and width D2) formed on a surface of insulating base material 11.

Copper wiring for n type 12 on insulating base material 11 of interconnection sheet 10 is formed correspondingly to silver electrode for n type 6 on the back surface of solar cell 8, and is formed to face a corresponding one silver electrode for n type 6.

Copper wiring for p type 13 on insulating base material 11 of interconnection sheet 10 is formed correspondingly to silver electrode for p type 7 on the back surface of solar cell 8, and is formed to face a corresponding one silver electrode for p type 7.

Copper wiring for n type 12 and copper wiring for p type 13 of interconnection sheet 10 are also each formed in the shape of a strip extending to the front surface side and/or the back surface side on the plane of sheet of FIG. 1.

Silver electrode for n type 6 of solar cell 8 and copper wiring for n type 12 of interconnection sheet 10 are electrically connected to constitute a connecting portion formed by silver electrode for n type 6 and copper wiring for n type 12.

Silver electrode for p type 7 of solar cell 8 and copper wiring for p type 13 of interconnection sheet 10 are also electrically connected to constitute a connecting portion formed by silver electrode for p type 7 and copper wiring for p type 13.

An insulating resin 16 is arranged in a region between solar cell 8 and interconnection sheet 10 other than the portion connecting silver electrode for n type 6 and copper wiring for n type 12 and the portion connecting silver electrode for p type 7 and copper wiring for p type 13.

In the solar cell with the interconnection sheet according to the first embodiment, width D2 of copper wiring for n type 12 of interconnection sheet 10 is larger than width D1 of silver electrode for n type 6 of solar cell 8, and width D2 of copper wiring for p type 13 of interconnection sheet 10 is larger than width D1 of silver electrode for p type 7 of solar cell 8. As a result, each silver electrode (silver electrode for n type 6, silver electrode for p type 7) of solar cell 8 can be placed so as not to protrude from the corresponding copper wiring (copper wiring for n type 12, copper wiring for p type 13) of interconnection sheet 10 at least in the width direction. Therefore, the electric field strength on the surfaces of the silver electrodes can be reduced as described below.

Silver electrode for n type 6 of solar cell 8 is placed such that a center line located at a center of silver electrode for n type 6 in the width direction (in the horizontal direction on the plane of sheet of FIG. 1) and extending in the longitudinal direction of silver electrode for n type 6 overlaps with a center line located at a center of copper wiring for n type 12 of interconnection sheet 10 in the width direction (in the horizontal direction on the plane of sheet of FIG. 1) and extending in the longitudinal direction of copper wiring for n type 12.

In addition, silver electrode for p type 7 of solar cell 8 is placed such that a center line located at a center of silver electrode for p type 7 in the width direction (in the horizontal direction on the plane of sheet of FIG. 1) and extending in the longitudinal direction of silver electrode for p type 7 overlaps with a center line located at a center of copper wiring for p type 13 of interconnection sheet 10 in the width direction (in the horizontal direction on the plane of sheet of FIG. 1) and extending in the longitudinal direction of copper wiring for p type 13.

As described above, each electrode and the corresponding wiring are positioned such that the center line of the electrode and the center line of the wiring form little angle and substantially match in terms of position. As a result, each silver electrode (silver electrode for n type 6, silver electrode for p type 7) of solar cell 8 can be placed so as not to protrude from the corresponding copper wiring (copper wiring for n type 12, copper wiring for p type 13) of interconnection sheet 10 at least in the width direction.

In addition, width D2 of each copper wiring (copper wiring for n type 12, copper wiring for p type 13) is preferably larger by 40 μm or more than width D1 of the corresponding silver electrode (silver electrode for n type 6, silver electrode for p type 7) placed correspondingly to the copper wiring. As a result, even if the accuracy at the time of positioning the silver electrode of solar cell 8 and the copper wiring of interconnection sheet 10 is taken into consideration, there is a tendency that the silver electrode can be placed so as not to protrude from the copper wiring.

The case where the silver electrode (silver electrode for n type 6, silver electrode for p type 7) of solar cell 8 does not protrude from the copper wiring (copper wiring for n type 12, copper wiring for p type 13) of interconnection sheet 10 in the width direction includes a case where a side surface of the silver electrode (silver electrode for n type 6, silver electrode for p type 7) of solar cell 8 is aligned with a side surface of the copper wiring (copper wiring for n type 12, copper wiring for p type 13) of interconnection sheet 10 (a case where an amount of protrusion of the silver electrode from the copper wiring in the width direction is zero).

In other words, an image of each silver electrode projected in the direction perpendicular to the surface of substrate 1 provided with the silver electrode (silver electrode for n type 6, silver electrode for p type 7) of solar cell 8 is located within a surface region of the corresponding copper wiring (copper wiring for n type 12, copper wiring for p type 13) of interconnection sheet 10 that faces the silver electrode.

Put another way, the silver electrode is arranged on the copper wiring such that the silver electrode (silver electrode for n type 6, silver electrode for p type 7) of solar cell 8 is hidden by the copper wiring (copper wiring for n type 12, copper wiring for p type 13) of interconnection sheet 10 and cannot be visually recognized when the solar cell with the interconnection sheet according to the first embodiment is viewed from the interconnection sheet 10 side in the direction perpendicular to the surface of substrate 1.

Furthermore, in the solar cell with the interconnection sheet according to the first embodiment, copper which is a metal material forming the copper wiring (copper wiring for n type 12, copper wiring for p type 13) of interconnection sheet 10 is a metal material that is less likely to cause ion migration than silver which is a metal material forming the silver electrode (silver electrode for n type 6, silver electrode for p type 7) of solar cell 8.

In the solar cell with the interconnection sheet according to the first embodiment having the above-described configuration, generation of a needle-like substance formed from metal ions that have undergone ion migration due to the electric field generated between adjacent connecting portions in which the silver electrode of solar cell 8 and the copper wiring of interconnection sheet 10 are connecting each other can be suppressed in a stable manner. Therefore, in the solar cell with the interconnection sheet according to the first embodiment, lowering of the properties of the solar cell with the interconnection sheet, which is caused by short circuit between the connecting portions resulting from the needle-like substance generated due to ion migration, can be suppressed in a stable manner. This has been found out from a simulation result below.

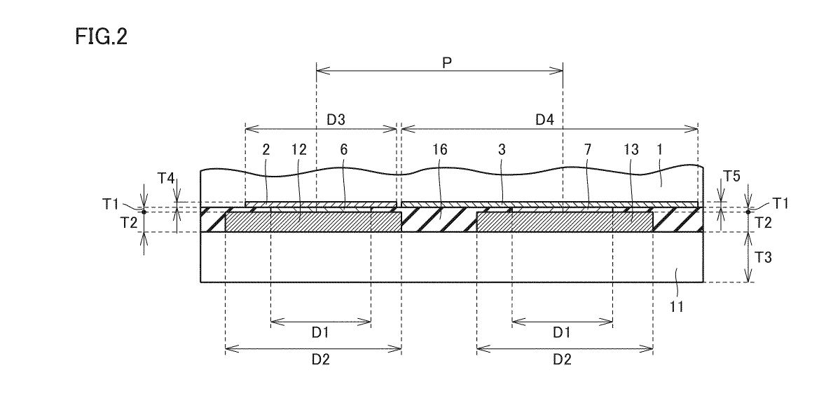

FIG. 2 shows a schematic enlarged cross-sectional view of the portion connecting the silver electrode of the solar cell and the copper wiring of the interconnection sheet and its surrounding portion, in a portion corresponding to one cycle of the solar cell with the interconnection sheet used in simulation. In other words, in the solar cell with the interconnection sheet used in simulation, the portion corresponding to one cycle shown in FIG. 2 appears repeatedly in the horizontal direction in FIG. 2.

An n-type silicon substrate (relative dielectric constant: 12) having a thickness of 200 μm was used as substrate 1, and a PET (polyester) film (relative dielectric constant: 3.2) having a thickness T3 of 100 μm was used as insulating base material 11. In addition, an insulating adhesive that was NCP (Non Conductive Paste) was used as insulating resin 16 placed in the region between substrate 1 and insulating base material 11.

A thickness T4 of n-type impurity diffusion region 2 was set to be 0.5 μm and a width D3 of n-type impurity diffusion region 2 was set to be 300 μm. A thickness T5 of p-type impurity diffusion region 3 was set to be 0.8 μm and a width D4 of p-type impurity diffusion region 3 was set to be 600 μm.

Thicknesses T1 of silver electrode for n type 6 and silver electrode for p type 7 were set to be 10 μm and widths D1 of silver electrode for n type 6 and silver electrode for p type 7 were set to be 200 μm.

Thicknesses T2 of copper wiring for n type 12 and copper wiring for p type 13 were set to be 35 μm and widths D2 of copper wiring for n type 12 and copper wiring for p type 13 were set to be 350 μm.

An epoxy resin (relative dielectric constant: 4.4) was used as insulating resin 16 placed between the solar cell and the interconnection sheet. On a region on the back surface of the n-type silicon substrate other than a region where silver electrode for n type 6 and silver electrode for p type 7 were formed, the passivation film (not shown) configured by a stacked structure of a silicon nitride film (relative dielectric constant: 7) and a silicon oxide film (relative dielectric constant: 3.9) was formed from the n-type silicon substrate side.

Furthermore, a pitch P between the electrodes (the shortest distance between the center of silver electrode for n type 6 in the width direction and the center of silver electrode for p type 7 in the width direction) was set to be 0.5 mm.

It is assumed that a voltage of +0.6 V was applied to silver electrode for p type 7, copper wiring for p type 13 and p-type impurity diffusion region 3 of the solar cell with the interconnection sheet set as described above, and that a voltage of 0 V was applied to the remaining portion (silver electrode for n type 6, n-type impurity diffusion region 2, and a region on the back surface of substrate 1 between n-type impurity diffusion region 2 and p-type impurity diffusion region 3).

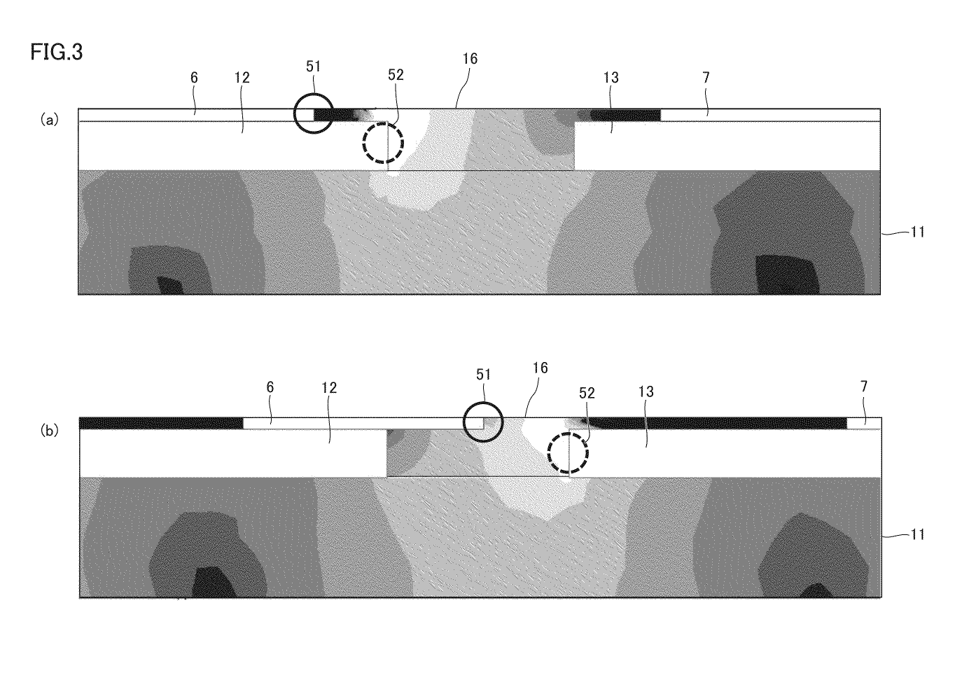

Simulation was performed about how the electric field strength distribution of the electric field generated between the adjacent connecting portions changes as a result of change in relative position of the silver electrodes (silver electrode for n type 6 and silver electrode for p type 7) of the solar cell with respect to the copper wirings (copper wiring for n type 12 and copper wiring for p type 13) of the interconnection sheet. The result of the simulation is shown in FIGS. 3(a) and 3(b). In FIGS. 3(a) and 3(b), the strength of the electric field is expressed in a stepwise manner using gradation, and lighter (whiter) color means higher electric field strength.

FIG. 3(a) shows the electric field strength distribution when the center of the silver electrode of the solar cell in the width direction matches the center of the copper wiring of the interconnection sheet in the width direction (i.e., when the copper wiring of the interconnection sheet protrudes from the silver electrode of the solar cell by 75 μm in the width direction (when the amount of protrusion of the silver electrode is −75 μm)).

FIG. 3(b) shows the electric field strength distribution when the center of the silver electrode of the solar cell in the width direction is displaced from the center of the copper wiring of the interconnection sheet in the width direction by 160 μm to the right side in the figure (i.e., when silver electrode for n type 6 protrudes from copper wiring for n type 12 on the left side in the figure by 85 μm (when the amount of protrusion of the silver electrode is +85 μm)).

As shown in FIGS. 3(a) and 3(b), when the amount of protrusion of the silver electrode is increased, a position 51 where the electric field strength of the silver electrode is maximum continues to be an end of the silver electrode in the width direction. However, a position 52 where the electric field strength of the copper wiring is maximum changes from an end of the copper wiring in the width direction on the left side to an end of the copper wiring in the width direction on the right side.

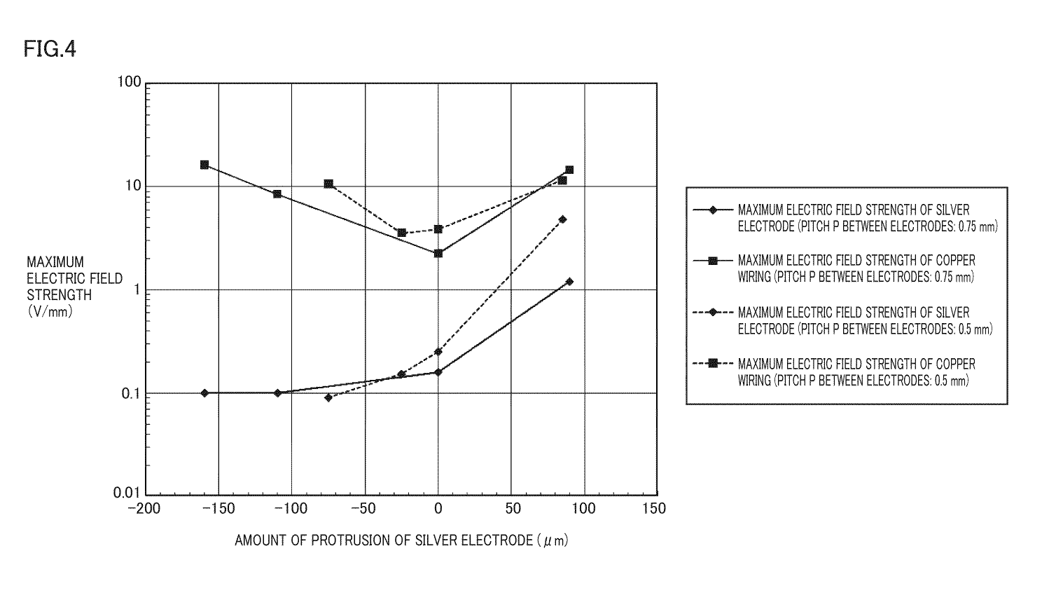

FIG. 4 shows a relationship between the amount of protrusion of the silver electrode (μm) and the electric field strength (V/mm) when the amount of protrusion of the silver electrode is variously changed to displace the relative position in the width direction of the silver electrode with respect to the copper wiring, while a position of the copper wiring of the interconnection sheet is fixed and a spacing between the silver electrodes of the solar cell is kept constant, and the aforementioned simulation is performed. The horizontal axis in FIG. 4 indicates the amount of protrusion of the silver electrode (μm), and the vertical axis in FIG. 4 indicates the electric field strength (V/mm). It should be noted that the electric field strength (V/mm) indicated by the vertical axis in FIG. 4 represents the maximum electric field strength in the silver electrode and the copper wiring in the case of each amount of protrusion of the silver electrode (μm) indicated by the horizontal axis in FIG. 4. FIG. 4 also shows a relationship between the amount of protrusion of the silver electrode (μm) and the electric field strength (V/mm) when pitch P between the electrodes is set to be 0.5 mm and 0.75 mm, the width of the copper wiring is set to be 550 μm and the width of the silver electrode is set to be 230 μm.

As is clear from the result shown in FIG. 4, in both cases where pitch P between the electrodes is 0.5 mm and where pitch P between the electrodes is 0.75 mm, the maximum electric field strength in the silver electrode and the copper wiring increases sharply when the amount of protrusion of the silver electrode (μm) becomes larger than zero (becomes a positive value).

FIG. 5 shows ion migration sensitivity of various types of metal materials. The vertical axis in FIG. 5 indicates various types of metal materials, and the horizontal axis (logarithmic axis) in FIG. 5 indicates the ion migration sensitivity of each metal material indicated by the vertical axis. As shown in FIG. 5, the ion migration sensitivity of silver is about 300 times as high as that of copper. It should be noted that FIG. 5 is based on the description on page 3 of “Corrosion Center News No. 017” (Sep. 1, 1998) edited by Japan Society of Corrosion Engineering. The horizontal axis in FIG. 5 is a logarithmic axis.

As described above, whether ion migration of a metal is likely to occur or not is determined by a product of a value of the ion migration sensitivity of each metal material and the electric field strength applied to the metal surface. In the solar cell with the interconnection sheet according to the first embodiment, a product of the ion migration sensitivity of silver shown in FIG. 5 and the electric field strength (V/mm) of the silver electrode shown in FIG. 4 is much larger than a product of the ion migration sensitivity of copper shown in FIG. 5 and the electric field strength (V/mm) of the copper wiring shown in FIG. 4. Therefore, in the solar cell with the interconnection sheet according to the first embodiment, ion migration is considered to be more likely to occur in ions of silver that is the metal material forming the silver electrode than ions of copper that is the metal material forming the copper wiring.

Based on the above discussion, in the solar cell with the interconnection sheet according to the first embodiment, suppressing the electric field strength of the silver electrode to be low is effective for suppressing lowering of the properties caused by ion migration of metal material in a stable manner.

Therefore, by arranging the end of each of silver electrode for n type 6 and silver electrode for p type 7 in the width direction so as not to protrude from the end of each of copper wiring for n type 12 and copper wiring for p type 13 in the width direction (setting the amount of protrusion of the silver electrode (μm) in the width direction to be zero or smaller), like the solar cell with the interconnection sheet according to the first embodiment, sharp increase in the electric field strength applied to the surfaces of silver electrode for n type 6 and silver electrode for p type 7 can be suppressed, and lowering of the properties caused by ion migration can be suppressed in a stable manner.

In other words, by positioning the copper wiring (copper wiring for n type 12, copper wiring for p type 13) corresponding to each silver electrode to intersect a surface perpendicular to the direction of the electric field applied between silver electrode for n type 6 and silver electrode for p type 7 of solar cell 8, the strength of the electric field generated on the surface of each of silver electrode for n type 6 and silver electrode for p type 7 can be reduced, and lowering of the properties caused by ion migration of metal material can be suppressed in a stable manner.

According to the result shown in FIG. 4, when pitch P between the electrodes is 0.75 mm, the maximum electric field strength of the silver electrode can be set at substantially the lowest level (0.1 (V/mm) or lower in the result shown in FIG. 4) and fluctuations in the maximum electric field strength of the silver electrode with respect to the amount of protrusion of the silver electrode (μm) can also be suppressed, if the amount of protrusion of the silver electrode (μm) is set to be −100 μm or smaller (an amount of protrusion of the copper wiring from the silver electrode is set to be 100 μm or larger).

Therefore, when pitch P between the electrodes is 0.75 mm, it is more preferable to cause copper wiring for n type 12 of interconnection sheet 10 connected to silver electrode for n type 6 to protrude from silver electrode for n type 6 by 100 μm or more in the direction of silver electrode for p type 7 arranged to face silver electrode for n type 6, and to cause copper wiring for p type 13 of interconnection sheet 10 connected to silver electrode for p type 7 to protrude from silver electrode for p type 7 by 100 μm or more in the direction of silver electrode for n type 6 arranged to face silver electrode for p type 7. In this case, there is little increase in the electric field strength applied to the silver electrode with respect to the amount of protrusion of the silver electrode (μm), and thus, lowering of the properties caused by ion migration of the silver electrode can be controlled in a more stable manner.

In addition, according to the result shown in FIG. 4, even when pitch P between the electrodes is 0.5 mm, it is considered that the maximum electric field strength of the silver electrode can be set at substantially the lowest level (0.1 (V/mm) or lower in the result shown in FIG. 4) and fluctuations in the maximum electric field strength of the silver electrode with respect to the amount of protrusion of the silver electrode (μm) can also be suppressed, similarly to the case where pitch P between the electrodes is 0.75 mm, if the amount of protrusion of the silver electrode (μm) is set to be −70 μm or smaller (the amount of protrusion of the copper wiring from the silver electrode is 70 μm or larger).

Therefore, when pitch P between the electrodes is 0.5 mm, it is more preferable to cause copper wiring for n type 12 of interconnection sheet 10 connected to silver electrode for n type 6 to protrude from silver electrode for n type 6 by 70 μm or more in the direction of silver electrode for p type 7 arranged to face silver electrode for n type 6, and to cause copper wiring for p type 13 of interconnection sheet 10 connected to silver electrode for p type 7 to protrude from silver electrode for p type 7 by 70 μm or more in the direction of silver electrode for n type 6 arranged to face silver electrode for p type 7. In this case as well, there is little increase in the electric field strength applied to the silver electrode with respect to the amount of protrusion of the silver electrode (μm), and thus, lowering of the properties caused by ion migration of the silver electrode can be controlled in a more stable manner.

Although the case where the electrode of solar cell 8 is configured by the silver electrode and the wiring of interconnection sheet 10 is configured by the copper wiring has been described above, it is needless to say that the electrode of solar cell 8 is not limited to the silver electrode, and it is needless to say that the wiring of interconnection sheet 10 is not limited to the copper wiring. However, silver is a metal material that is likely to cause ion migration, and thus, the present invention is considered to be particularly effective when the electrode of solar cell 8 is a silver electrode containing silver and the wiring of interconnection sheet 10 is a wiring containing a metal whose ion migration sensitivity is lower than that of silver by an order of magnitude or more.

In addition, in the foregoing, widths D1 of silver electrode for n type 6 and silver electrode for p type 7 can be set to be, for example, 100 μm or larger and 300 μm or smaller, and thicknesses T1 can be set to be, for example, 5 μm or larger and 15 μm or smaller. It should be noted that widths D1 do not necessarily need to have the same value and thicknesses T1 do not necessarily need to have the same value, either.

In addition, in the foregoing, widths D2 of copper wiring for n type 12 and copper wiring for p type 13 can be set to be, for example, 300 μm or larger and 600 μm or smaller, and thicknesses T2 can be set to be, for example, 10 μm or larger and 50 μm or smaller. It should be noted that widths D2 do not necessarily need to have the same value and thicknesses T2 do not necessarily need to have the same value, either.

One example of a method for manufacturing the solar cell with the interconnection sheet according to the first embodiment will be described hereinafter. One example of a method for manufacturing solar cell 8, one example of a method for manufacturing interconnection sheet 10, and one example of a method for manufacturing the solar cell with the interconnection sheet will be described in this order hereinafter. However, manufacturing of solar cell 8 and manufacturing of interconnection sheet 10 may be interchanged or may be performed simultaneously.

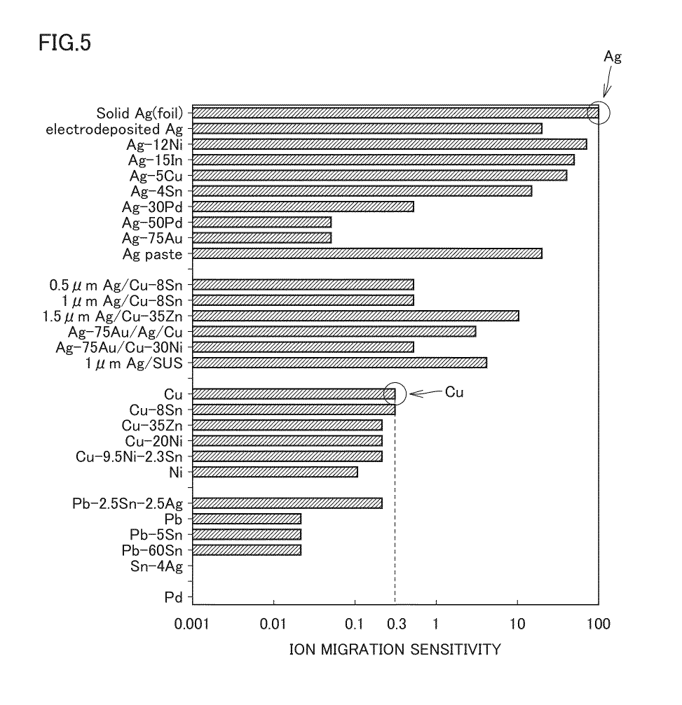

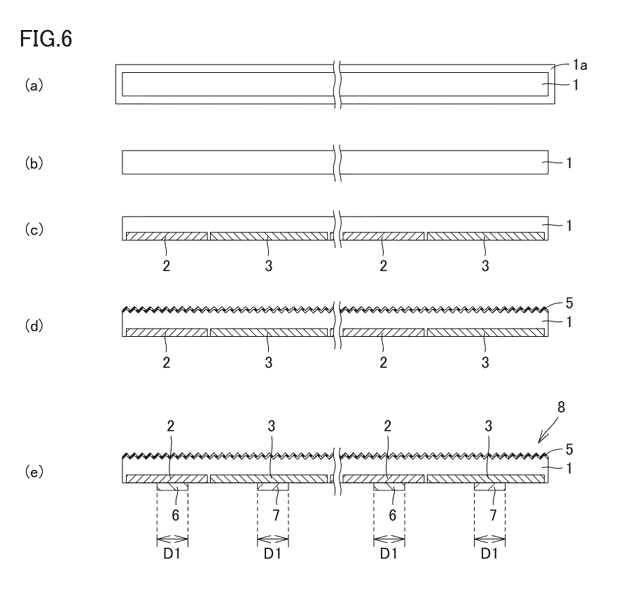

One example of the method for manufacturing solar cell 8 will be described hereinafter with reference to schematic cross-sectional views in FIGS. 6(a) to 6(e).

First, as shown in FIG. 6(a), by slicing an ingot, for example, substrate 1 having a slice damage 1a on a surface of substrate 1 is prepared.

A silicon substrate made of polycrystalline silicon or monocrystalline silicon having the n or p conductivity type can, for example, be used as substrate 1.

Next, as shown in FIG. 6(b), slice damage 1a on the surface of substrate 1 is removed.

When substrate 1 is configured by the aforementioned silicon substrate, for example, slice damage 1a can be removed by etching the surface of the silicon substrate after slicing as described above with mixed acid of a hydrogen fluoride aqueous solution and nitric acid, with an alkaline aqueous solution such as sodium hydroxide, or the like. Although the size and the shape of substrate 1 after removal of slice damage 1a are not particularly limited, substrate 1 having a thickness of 100 μm or larger and 500 μm or smaller can be used, for example.

Next, as shown in FIG. 6(c), n-type impurity diffusion region 2 and p-type impurity diffusion region 3 are formed on the back surface of substrate 1.

N-type impurity diffusion region 2 can be formed, for example, by a method such as vapor-phase diffusion using a gas containing an n-type impurity, or application diffusion in which heat treatment is performed after a paste containing the n-type impurity is applied. P-type impurity diffusion region 3 can be formed, for example, by a method such as vapor-phase diffusion using a gas containing a p-type impurity, or application diffusion in which heat treatment is performed after a paste containing the p-type impurity is applied.

A gas containing the n-type impurity such as phosphorus like POCl₃, for example, can be used as the gas containing the n-type impurity. A gas containing the p-type impurity such as boron like BBr₃, for example, can be used as the gas containing the p-type impurity.

N-type impurity diffusion region 2 is not particularly limited as long as n-type impurity diffusion region 2 is a region containing the n-type impurity and exhibiting the n conductivity type. Phosphorus and the like can, for example, be used as the n-type impurity.

P-type impurity diffusion region 3 is not particularly limited as long as p-type impurity diffusion region 3 is a region containing the p-type impurity and exhibiting the p conductivity type. Boron and/or aluminum can, for example, be used as the p-type impurity.

The passivation film may be formed on the back surface of substrate 1 having n-type impurity diffusion region 2 and p-type impurity diffusion region 3 formed thereon. The passivation film can be fabricated, for example, by forming a silicon nitride film, a silicon oxide film or a stacked structure of the silicon nitride film and the silicon oxide film using a method such as a thermal oxidation method or a plasma CVD (Chemical Vapor Deposition) method. The thickness of the passivation film can be set to be, for example, 0.05 μm or larger and 1 μm or smaller.

Next, as shown in FIG. 6(d), the uneven structure such as the textured structure is formed on the entire light receiving surface of substrate 1, and thereafter, anti-reflection film 5 is formed on this uneven structure.

The textured structure can be formed, for example, by etching the light receiving surface of substrate 1. When substrate 1 is the silicon substrate, for example, the textured structure can be formed by etching the light receiving surface of substrate 1 with an etchant obtained by heating an alkaline aqueous solution such as, for example, sodium hydroxide or potassium hydroxide to which isopropyl alcohol is added to 70° C. or higher and 80° C. or lower, for example.

Anti-reflection film 5 can be formed, for example, by the plasma CVD method. A silicon nitride film and the like can, for example, be used as anti-reflection film 5, although anti-reflection film 5 is not limited thereto.

When the passivation film is formed on the back surface of substrate 1, contact holes that expose at least a part of a surface of n-type impurity diffusion region 2 and at least a part of a surface of p-type impurity diffusion region 3 may be formed by removing a part of the passivation film on the back surface of substrate 1.

The contact hole can be formed, for example, by a method for forming a resist pattern, which has an opening in a portion corresponding to a location where the contact hole will be formed, on the passivation film by means of a photolithography technique, and thereafter, removing the passivation film from the opening of the resist pattern by etching and the like, a method for applying an etching paste to a portion of the passivation film corresponding to a location where the contact hole will be formed and heating the etching paste, thereby etching and removing the passivation film, or the like.

Next, as shown in FIG. 6(e), silver electrode for n type 6 that is in contact with n-type impurity diffusion region 2 on the back surface of substrate 1 is formed, and silver electrode for p type 7 that is in contact with p-type impurity diffusion region 3 is formed.

Silver electrode for n type 6 and silver electrode for p type 7 can be formed, for example, by applying a silver paste to be in contact with n-type impurity diffusion region 2 and p-type impurity diffusion region 3, and thereafter, firing the silver paste, respectively. As a result, each of silver electrode for n type 6 and silver electrode for p type 7 forms an electrode containing silver at least on a surface thereof.

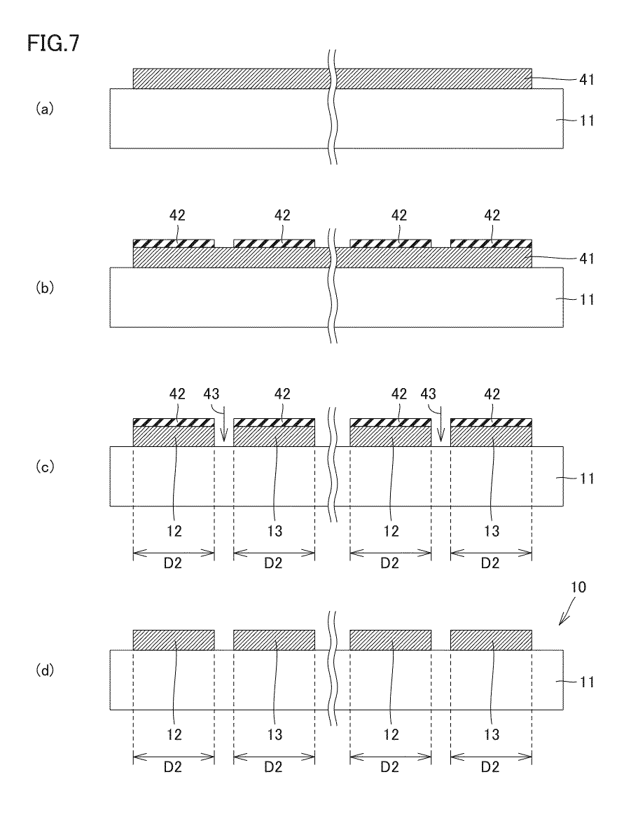

One example of the method for manufacturing interconnection sheet 10 will be described hereinafter with reference to schematic cross-sectional views in FIGS. 7(a) to 7(d).

First, as shown in FIG. 7(a), a conductive layer 41 made of copper is formed on the surface of insulating base material 11.

A substrate made of a resin such as polyester, polyethylene naphthalate or polyimide can, for example, be used as insulating base material 11, although insulating base material 11 is not limited thereto. The thickness of insulating base material 11 can be set to be, for example, 10 μm or larger and 200 μm or smaller.

Next, as shown in FIG. 7(b), a resist 42 is formed on conductive layer 41 on the surface of insulating base material 11.

Resist 42 is formed into a shape having an opening in a location other than a location where the copper wiring of interconnection sheet 10 such as copper wiring for n type 12 and copper wiring for p type 13 remains. A conventionally known resist can, for example, be used as resist 42, and a resist formed by curing a resin applied to a prescribed position by a method such as screen printing, dispenser application or inkjet application can, for example, be used.

Next, as shown in FIG. 7(c), conductive layer 41 is patterned by removing, in the direction of an arrow 43, conductive layer 41 located in a location where conductive layer 41 is exposed from resist 42. The copper wiring of interconnection sheet 10 such as copper wiring for n type 12 and copper wiring for p type 13 is thus formed from the remaining portion of conductive layer 41.

Conductive layer 41 can be removed, for example, by wet etching with an acid or alkaline solution.

Next, as shown in FIG. 7(d), resist 42 is all removed from a surface of copper wiring for n type 12 and a surface of copper wiring for p type 13. Interconnection sheet 10 having copper wiring for n type 12 and copper wiring for p type 13 formed on insulating base material 11 is thus fabricated. In addition to copper wiring for n type 12 and copper wiring for p type 13, a wiring for electrically connecting a plurality of copper wirings for n type 12, a wiring for electrically connecting a plurality of copper wirings for p type 13, a wiring for electrically connecting a plurality of solar cells 8, and the like may be formed on insulating base material 11.

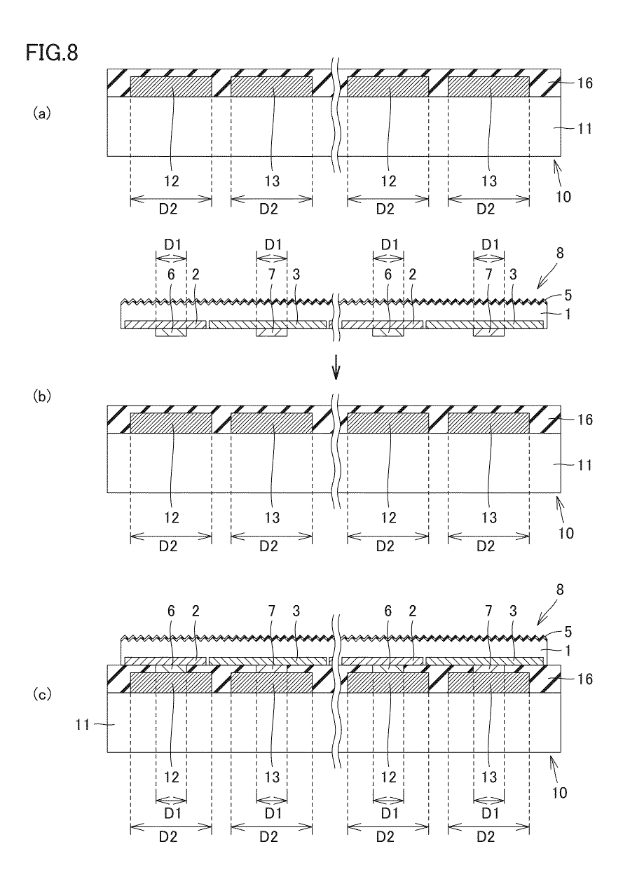

One example of the method for manufacturing the solar cell with the interconnection sheet according to the first embodiment will be described hereinafter with reference to schematic cross-sectional views in FIGS. 8(a) to 8(c).

First, as shown in FIG. 8(a), insulating resin 16 is applied onto the surface of insulating base material 11 of interconnection sheet 10 fabricated as described above.

An electrically-insulating thermosetting and/or light curing resin composition and the like including, as a resin component, any one of an epoxy resin, an acrylic resin, and a mixed resin of the epoxy resin and the acrylic resin can, for example, be used as insulating resin 16. As a component other than the resin component, insulating resin 16 may also include, for example, one or more types of conventionally known additives such as a curing agent.

Next, as shown in FIG. 8(b), solar cell 8 is placed on interconnection sheet 10.

Solar cell 8 is placed on interconnection sheet 10 as follows: silver electrode for n type 6 is placed on copper wiring for n type 12 such that the end of silver electrode for n type 6 in the width direction does not protrude from the end of copper wiring for n type 12 in the width direction, and silver electrode for p type 7 is placed on copper wiring for p type 13 such that the end of silver electrode for p type 7 in the width direction does not protrude from the end of copper wiring for p type 13 in the width direction.

Next, as shown in FIG. 8(c), insulating resin 16 is heated and/or irradiated with light to solidify insulating resin 16. The solar cell with the interconnection sheet according to the first embodiment is thus fabricated.

The solar cell with the interconnection sheet according to the first embodiment can be fabricated by curing insulating resin 16 placed between solar cell 8 and interconnection sheet 10, with the silver electrode of solar cell 8 being in contact with the copper wiring of interconnection sheet 10.

The solar cell with the interconnection sheet according to the first embodiment can also be configured such that a plurality of solar cells 8 are placed on interconnection sheet 10 and these solar cells 8 are electrically connected in series.

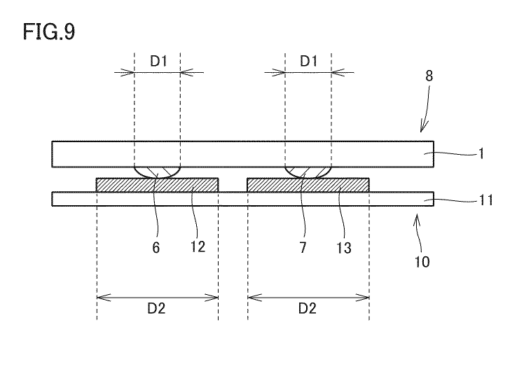

As shown in a schematic cross-sectional view in FIG. 9, for example, silver electrode for n type 6 and silver electrode for p type 7 of the solar cell with the interconnection sheet according to the first embodiment may also be configured to have an oval cross-sectional shape. It should be noted that members other than substrate 1, silver electrode for n type 6, silver electrode for p type 7, insulating base material 11, copper wiring for n type 12, and copper wiring for p type 13 are not shown in FIG. 9 for convenience in description.

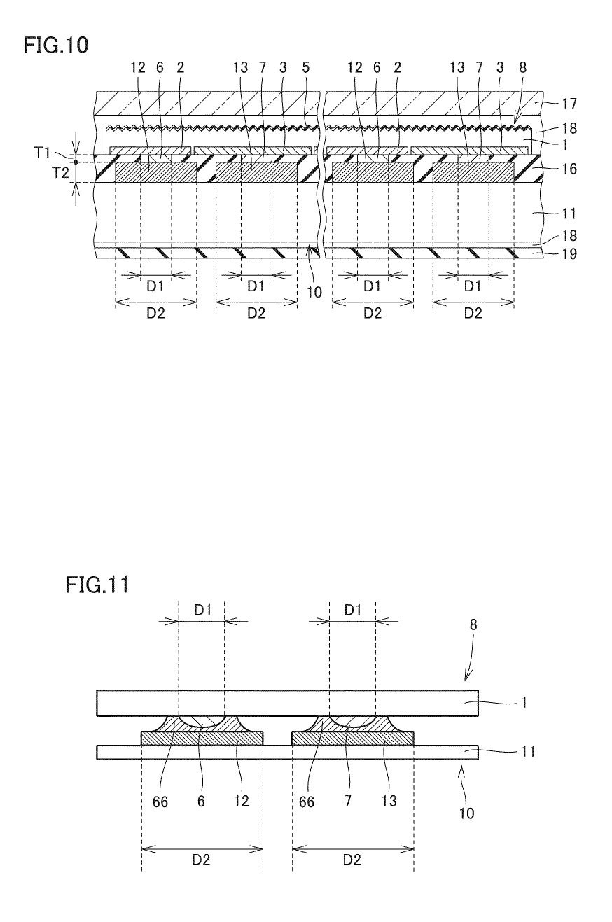

Thereafter, as shown in a schematic cross-sectional view in FIG. 10, for example, the solar cell with the interconnection sheet according to the first embodiment fabricated as described above is sealed into a sealant 18 between a transparent substrate 17 and a back surface protection member 19. A solar cell module including the solar cell with the interconnection sheet according to the first embodiment can be thus fabricated.

A substrate such as, for example, a glass substrate through which light having entered the solar cell module can pass can be used as transparent substrate 17. A resin and the like such as, for example, ethylene vinyl acetate through which light having entered the solar cell module can pass can be used as sealant 18. A member and the like such as, for example, a polyester film that can protect the solar cell with the interconnection sheet can be used as back surface protection member 19.

The case where the back electrode type solar cell configured to have both the silver electrode for n type and the silver electrode for p type formed only on the one surface side (on the back surface side) of the substrate is used as the solar cell has been described above. The concept of the solar cell according to the present invention, however, includes not only the above-described back electrode type solar cell, but also a so-called back contact type solar cell (a solar cell configured such that a current is taken out from the back surface side opposite to the light receiving surface side of the solar cell) such as an MWT (Metal Wrap Through) cell (a solar cell configured such that a part of an electrode is arranged in a through hole provided in a substrate), and a solar cell having a silver electrode for n type and/or a silver electrode for p type formed on a surface opposite to a back surface of a substrate as described above and/or on a side surface of the substrate.

The concept of the solar cell with the interconnection sheet according to the present invention includes not only the configuration in which the plurality of solar cells 8 are placed on interconnection sheet 10 and the solar cells 8 are electrically connected, but also a configuration in which one solar cell is placed on an interconnection sheet.

### Second Embodiment

FIG. 11 shows a schematic cross-sectional view of a solar cell with an interconnection sheet according to a second embodiment, which is another example of the solar cell with the interconnection sheet according to the present invention.

The solar cell with the interconnection sheet according to the second embodiment has one feature that electrical connection between silver electrode for n type 6 of solar cell 8 and copper wiring for n type 12 of interconnection sheet 10 as well as electrical connection between silver electrode for p type 7 of solar cell 8 and copper wiring for p type 13 of interconnection sheet 10 are established by a conductive adhesive 66.

In this case, electrical resistance at a portion connecting the silver electrode (silver electrode for n type 6, silver electrode for p type 7) of solar cell 8 and the copper wiring (copper wiring for n type 12, copper wiring for p type 13) of interconnection sheet 10 can be reduced and a voltage drop at this connecting portion can be reduced, and thus, the output power of the solar cell with the interconnection sheet can be enhanced. In addition, in this case, the silver electrode of solar cell 8 and the copper wiring of interconnection sheet 10 can be fixed by conductive adhesive 66, and thus, an amount of above-described insulating resin 16 used can be reduced.

Conductive adhesive 66 is preferably made of a metal material that is less likely to cause ion migration than the metal material forming the silver electrode (silver electrode for n type 6, silver electrode for p type 7) of solar cell 8. As a result, at a portion where conductive adhesive 66 is in contact with the surface of the silver electrode of solar cell 8, conductive adhesive 66 has the same potential as that of the silver electrode, and thus, the electric field is not generated on the surface of the silver electrode. Therefore, there is a tendency that ion migration of the metal material forming the silver electrode can be further suppressed.

The copper wiring (copper wiring for n type 12, copper wiring for p type 13) of interconnection sheet 10 is preferably made of a metal material that is less likely to cause ion migration than the metal material forming conductive adhesive 66. As a result, similarly to the first embodiment, ion migration of conductive adhesive 66 can be suppressed by the copper wiring (copper wiring for n type 12, copper wiring for p type 13) of interconnection sheet 10, while suppressing ion migration of the silver electrode (silver electrode for n type 6, silver electrode for p type 7) of solar cell 8 by conductive adhesive 66.

When the silver electrode (silver electrode for n type 6, silver electrode for p type 7) of solar cell 8 is in contact with the copper wiring (copper wiring for n type 12, copper wiring for p type 13) of interconnection sheet 10, it is more preferable that a surface other than the surface of the silver electrode that is in contact with the copper wiring is covered with conductive adhesive 66 made of the metal material that is less likely to cause ion migration than the metal material forming the silver electrode. As a result, the surface of the silver electrode can be covered with conductive adhesive 66 having the same potential as that of the silver electrode and made of the metal material that is less likely to cause ion migration than the metal material forming the silver electrode, and thus, generation of the electric field on the surface of the silver electrode can be prevented. Therefore, there is a stronger tendency that ion migration of the metal material forming the silver electrode can be further suppressed.

As described above, in the solar cell with the interconnection sheet according to the second embodiment, lowering of the properties caused by ion migration can be suppressed in a more stable manner.

It should be understood that the embodiments disclosed herein are illustrative and not limitative in any respect. The scope of the present invention is defined by the terms of the claims, rather than the description above, and is intended to include any modifications within the scope and meaning equivalent to the terms of the claims.

### INDUSTRIAL APPLICABILITY

The present invention can be used in the solar cell with the interconnection sheet and the solar cell module.

### REFERENCE SIGNS LIST

1 substrate; 1a slice damage; 2 n-type impurity diffusion region; 3 p-type impurity diffusion region; 5 anti-reflection film; 6 silver electrode for n type; 7 silver electrode for p type; 8 solar cell; 10 interconnection sheet; 11 insulating base material; 12 copper wiring for n type; 13 copper wiring for p type; 16 insulating resin; 17 transparent substrate; 18 sealant; 19 back surface protection member; 41 conductive layer; 42 resist; 43 arrow; 51 position where the electric field strength of the silver electrode is maximum; 52 position where the electric field strength of the copper wiring is maximum; 66 conductive adhesive

1-10. (canceled)

11. A solar cell with an interconnection sheet, comprising:
a back electrode type solar cell provided with a first electrode and a second electrode having a polarity different from that of said first electrode on one surface of a substrate; and
an interconnection sheet provided with a first wiring electrically connected to said first electrode and a second wiring electrically connected to said second electrode, wherein
said first wiring is made of a material that is less likely to cause ion migration than a metal material forming said first electrode,
said second wiring is made of a material that is less likely to cause ion migration than a metal material forming said second electrode,
a width of said first wiring is larger than a width of said first electrode,
a width of said second wiring is larger than a width of said second electrode,
a distance from an end of said first electrode to an end of said first wiring is 100 μm or longer, and
a distance from an end of said second electrode to an end of said second wiring is 100 μm or longer.

12. The solar cell with the interconnection sheet according to claim 11, wherein
said first electrode and said second electrode contain silver and said first wiring and said second wiring contain copper.

13. A solar cell module, comprising the solar cell with the interconnection sheet as recited in claim 11.

14. A method for manufacturing a solar cell with an interconnection sheet including: a back electrode type solar cell provided with a first electrode and a second electrode having a polarity different from that of said first electrode on one surface of a substrate; and an interconnection sheet provided with a first wiring electrically connected to said first electrode and a second wiring electrically connected to said second electrode, wherein
in said interconnection sheet, said first wiring is made of a material that is less likely to cause ion migration than a metal material forming said first electrode, said second wiring is made of a material that is less likely to cause ion migration than a metal material forming said second electrode, a width of said first wiring is larger than a width of said first electrode, and a width of said second wiring is larger than a width of said second electrode,
the method comprising the step of:
electrically connecting said first electrode and said first wiring such that a distance from an end of said first electrode to an end of said first wiring is 100 μm or longer, and electrically connecting said second electrode and said second wiring such that a distance from an end of said second electrode to an end of said second wiring is 100 μm or longer.
